(19) United States
(12) Patent Application Publication
(10) Pub. No.: US 2005/0279455 A1
(43) Pub. Date: Dec. 22, 2005

(54) Plasma reactor for surface modification of objects

(76) Inventors: Harald Wanka, Blaustein (DE); Johann Georg Reichert, Blaubeuren (DE); Hans-Peter Voelk, Griesingen (DE); Moritz Heintze, Ulm (DE)

Correspondence Address: BAKER & BOTTS, 30 ROCKEFELLER PLAZA, NEW YORK, NY, 10112, US

(21) Appl. No.: 11/108,190

(22) Filed: Apr. 18, 2005

(30) Foreign Application Priority Data
Apr. 20, 2004 (DE) 10 2004 019 741.5

(51) Int. Cl. C23F 1/00; C23C 16/00

(52) U.S. Cl. 156/345.31; 118/719; 118/733; 118/723 R; 156/345.33; 156/345.34

(57) ABSTRACT

A plasma reactor is configured for rapid, simple and selective cleaning of plasma sources and adjacent areas of the processing chamber. The plasma reactor includes a processing chamber having a plurality of plasma zones, each associated with its own plasma source and/or a remote or downstream plasma source. The plasma reactor is configured so that substrates can be transported past the individual plasma sources in a processing mode in which the substrates are exposed to processing gasses chemically activated by the plasmas of the individual plasma sources. The plasma sources or zones can be selectively isolated or shielded from the substrates. Accordingly, an isolated plasma source can be selectively switched to a cleaning or etch mode without interrupting the processing flow of the substrates through the plasma reactor

### CROSS REFERENCE TO RELATED APPLICATIONS

This application claims the benefit of German Patent Application No. 10 2004 019 741.5 filed Apr. 20, 2004, which is hereby incorporated by reference in its entirety herein.

### FIELD OF THE INVENTION

The invention relates to a plasma reactor for surface coating or modification of objects and/or substrates by plasma processes in a processing chamber. In particular the invention relates to a plasma process at reduced pressure, with an entrance lock to the processing chamber and an exit lock.

### BACKGROUND OF THE INVENTION

Customarily, plasma reactors are employed as processing chambers, for example in semiconductor technology, for coating of wafers, other semiconductor structures or other substrates. The substrates or wafers are placed in the processing chamber by way of an entrance lock where, after placement in the processing chamber, a suitable pressure for the ensuing coating or processing operation, is generated by a vacuum pump. As soon as the required pressure, which may for example be 0.1 to 0.2 mbar, has been reached, the plasma reactor is activated with a high-frequency source. The plasma reactor may be activated via, for example, a capacitive electrode, which introduces a corresponding high-frequency energy into the processing chamber. At the same time, a suitable gas is introduced into the processing chamber.

By application of the high-frequency energy to the electrode, a processing gas is ionized in the processing chamber to generate a plasma. The substrate or material to be processed, which is located in the processing chamber (also designated as the receptacle), is exposed to the plasma. During the processing operation, fresh processing gas is added to the plasma reactor continuously, and at the same time contaminated or consumed gas is drawn off.

After processing of the substrate in the processing chamber is complete, the substrate is passed to the outside by way of an exit lock, in which at first the normal ambient pressure is established. The exit lock at the same time ensures that no processing gas can get into the environment.

It is well known that in coating operations in a processing chamber, for example a vacuum chamber, the inside walls of the chamber as well as the plasma source itself are always coated as well. These coatings, according to the prior art heretofore disclosed, cannot be prevented. The result is that the productivity of such a system is limited by the parasitic (undesirable) coatings on the plasma source or other components of the processing chamber. Upon reaching a pre-assigned boundary layer thickness, these deposits must be removed.

According to the past prior art, for example, as customary in the microelectronics industry, the processing chamber is cleaned by in situ etching (e.g. plasma etching) after the parasitic coatings on the plasma source and the other components, exceed a boundary layer thickness. Alternatively, the processing chamber may of course be aerated, opened and then cleaned mechanically. A disadvantage of both methods, of course, is that the productivity of the system is not inappreciably restricted, since no coating can be carried out during cleaning.

Consideration is now being given to ways of improving plasma processing systems and methods. In particular, attention is directed to improving plasma reactor structures and operations. Desirable plasma reactors may have uniformly high productivity, and permit rapid, simple and selective cleaning of the plasma sources and adjoining portions of the processing chamber.

### SUMMARY OF THE INVENTION

A plasma reactor capable of uniformly high productivity is provided. The plasma reactor is configured so that the plasma sources and adjoining portions of the processing chamber can be cleaned if necessary rapidly in a simple and selective manner.

The plasma reactor may include a plurality of plasma zones (at least two) corresponding to a plurality of plasma sources. The plasma reactor is designed so that the substrates can be moved past the plasma sources, and being meanwhile exposed to the processing gasses that are chemically activated by the plasma of at least one of the plasma source. At least one of the plasma sources can be selectively isolated from acting on the substrates to be processed and/or the processing chamber portions. When isolated, a plasma source or sources and the region of the processing chamber surrounding them can be supplied with an etching gas for in-situ cleaning (e.g., of parasitic coatings).

Thus, the processing chamber and the plasma reactor can be freed from parasitic impurities or coatings without need to open the processing chamber for external cleaning or to interrupt production (coating or surface modification) for the duration of an in situ cleaning.

In a first embodiment of the inventive plasma reactor, seals are provided for the isolation of individual plasma sources The seals may be configured, for example, as linearly displaceable slides, or in the case of linear plasma sources, as shieldings swingable in front of the linear plasma sources. In cases where swingable shieldings are deployed in front of the plasma source, the swingable shieldings may be advantageously configured so that they can be swung behind the linear plasma source when not in use. In the case of elongated plasma sources, the shielding of each plasma source consists preferably of cylindrical segments.

Alternatively or additionally, provision may be made for the isolation of individual plasma sources by a suitable gas flow arrangements in the processing chamber. The gas flow arrangements may be configured so that a pressure difference is generated between the isolated plasma source and the other plasma sources.

The inventive plasma reactors advantageously make it possible to perform an in situ etching of individual plasma sources to eliminate parasitic coatings, and at the same time continue processing of the substrates with other plasma sources. An interruption of the processes of treating the substrates for etch cleaning is no longer required. This can result in a considerable gain of productivity.

In a processing operation using the plasma reactors, substrates pass through several, but at least two, plasma zones in the processing chamber, in which they are exposed to the processing gas chemically activated by the plasma. In each zone, the plasma source can be isolated from the substrates by a suitable device (e.g., shielding or gas flow). Then etching gasses are supplied to the isolated plasma source instead of the processing gasses, so that a cleaning of the plasma source and the surrounding regions in the processing chamber can take place by plasma etching with the help of the etching gasses, thus removing the parasitic coatings.

During the cleaning operations involving a particular plasma source, the substrates can be carried past the particular plasma source without allowing the etching gasses to act on the substrate surface. The coating or surface treatment of the substrates can take place using the other plasma source(s).

If in order to attain the required plasma treatment rates (e.g., layer growth rates) on the substrates, several plasma sources are applied in succession, then if necessary, at any time, one or more plasma sources may be freely etched without interfering with the throughput of the substrates.

In the inventive plasma reactors, each plasma source can be switched between the two operating conditions—deposition and etching—without significant interruption of the throughput of substrates. Here, the isolation of the substrates and the etching (cleaning) take place without change in the relative location of substrate to electrode, some displacement e.g. of the electrode being possible inside the processing chamber.

### BRIEF DESCRIPTION OF THE DRAWINGS

Further features of the invention, its nature, and various advantages will be more apparent from the following detailed description and the accompanying drawings, wherein like reference characters represent like elements throughout, and in which:

FIG. 1 is a schematic representation of an exemplary plasma reactor having as components a pair of plasma sources, a reaction chamber and a re-etching chambers arranged in an outer chamber. The components are arranged so that the plasma sources can be alternately position in either the reaction chamber or the re-etching chamber in accordance with the principle sof the present invention.

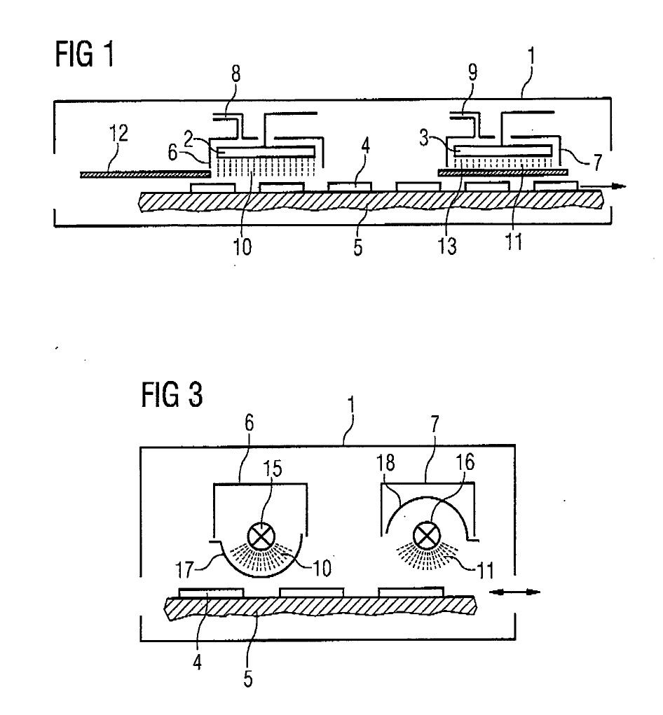

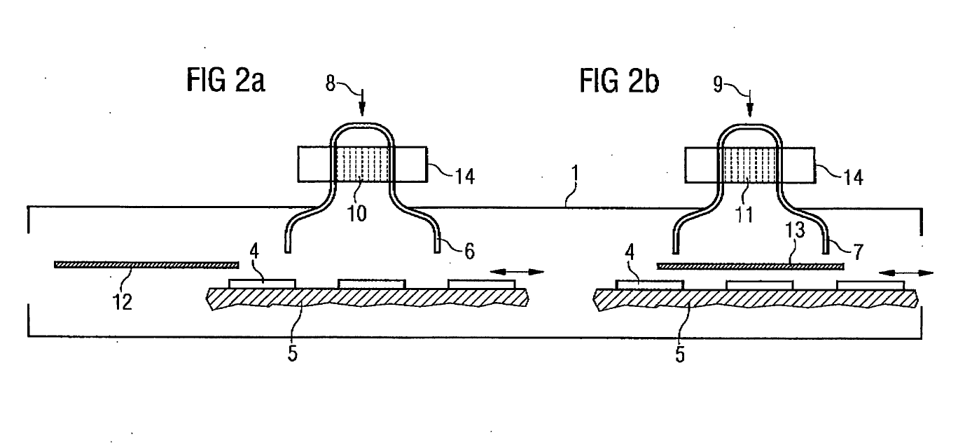

The following is a list of the reference numerals used in FIGS. 1-3:
1 processing chamber
2 plasma source
3 plasma source
4 substrate
5 substrate carrier
6 housing
7 housing
8 supply means
9 supply means
10 plasma
1 1 plasma
12 slide
13 slide
14 remote or downstream plasma source
15 linear plasma source
16 linear plasma source
17 rotary slide
18 rotary slide

### DETAILED DESCRIPTION OF THE INVENTION

The present invention provides plasma reactors having a plurality of plasma sources for plasma treatment or processing of substrates. The plasma sources are configured in a processing chamber so that any one of them can be switched to a cleaning or etching mode without interrupting the processing flow or throughput of substrates in the plasma reactor.

In FIG. 1, is a schematic representation of plasma reactor in which two plasma sources 2 and 3 arranged side-by-side in a processing chamber 1 with substrates 4 being carried past below. The substrates 4 are here distanced side-by-side on a substrate carrier 5, being carried past under the plasma sources 2 and 3. The plasma sources 2 and 3 are inside housings or shielding 6 and 7, respectively. The housing 6 and 7 may be made of quartz glass or metal. The housings or sheildings 6 and 7 are provided with supply means 8 and 9 for supply of processing gasses and etching gas, by which means processing gasses or etching gasses can be supplied according to the current operating condition or mode. The plasma sources 2 and 3 are each connected to high-frequency sources (not shown) in order to generate plasma 10 and 11, respectively, which are required in each instance for processing. Further, processing chamber 1 is connected to a vacuum pump (not shown) to generate the desired vacuum for operation.

Further, slides 12 and 13 are provided under housings 6 and 7, respectively. The slides are capable of being carried between the plasma sources 2 and 3 and the substrates 4. The slides provide means for making the corresponding plasma spaces largely separable from the other regions of the processing chamber, (e.g., so that the plasma 11 cannot reach the substrates 4).

FIG. 1 at the left shows plasma source 2 with corresponding plasma 10 in coating condition, and at the right shows plasma source 3 in closed condition, during etch cleaning.

FIG. 2 is a schematic representation of another plasma reactor configured according to the invention. The plasma reactor has a processing chamber 1 in which any remote or downstream plasma sources 14 are arranged. The plasma sources are configured with supply means (e.g., means 8 and 9) for processing or etching gasses. The left-hand portion of the drawing (FIG. 2a) shows the remote or downstream plasma source 14 with corresponding plasma 10 in coating condition, and at right the remote or downstream plasma source 14 in closed condition (FIG. 2b) during etch cleaning.

FIG. 3 shows a special embodiment of the inventive plasma reactor configurations. The plasma reactor include a processing chamber 1 in which linear plasma sources 15 and 16 are disposed inside respective housings 6 and 7. Unlike the linear slides in the preceding plasma reactor embodiments, here rotary slides 17 and 18 are provided to shield plasmas 10 and 11 from substrates 4 transported on substrate carrier 5.

On the left side of the drawing in FIG. 3, the rotary slide (17) is shown in closed position, i.e. in a cleaning position, and on the right-hand side of the drawing, the rotary slide (18) is shown in open position.

The invention is also suitable for a plasma reactor in which, for technical processing reasons, several plasma sources (e.g., sources 2, 3; 14; 15, 16) are arranged side-by-side, in order, for example, to produce a multilayer structure on the substrates. If all plasma sources housings (e.g., housings 6, 7 etc.) are here equipped with slides or shields according to the invention, then the individual plasma sources can be separated and cleaned in situ without interruption of the multilayer plasma coating operation in the plasma reactor.

It will be understood that the foregoing is only illustrative of the principles of the invention, and that various modifications can be made by those skilled in the art without departing from the scope and spirit of the invention.

1-8. (canceled)

9. A plasma reactor for surface coating or modification of objects and/or substrates by plasma processes, the plasma reactor comprising:
a processing chamber;
an arrangement of a plurality of plasma processing zones disposed in said processing chamber, each plasma processing zone associated with a plasma source;
a substrate transport mechanism that can be activated to move substrates through the plasma processing zones, whereby the substrates can be exposed to process gasses that are chemically activated by the plasmas of the associated plasma sources; and
plasma source isolation mechanisms that can be activated to selectively isolate at least one of the plasma sources from the substrates being moved through the processing chamber,
whereby the isolated plasma source can be operated in an etch mode or local cleaning process without affecting the substrates being moved through the processing chamber past the isolated plasma source

10. The plasma reactor of claim 9 wherein the plasma source isolation mechanisms comprise seals.

11. The plasma reactor of claim 9 wherein the plasma source isolation mechanisms comprise sliding structures

12. The plasma reactor of claim 9 wherein the plasma sources comprise a linear plasma source, and wherein the plasma source isolation mechanisms comprise a rotary slide that is swingable in front of the linear plasma source.

13. The plasma reactor of claim 12 wherein the rotary slide is swingable behind the linear plasma source when not in use.

14. The plasma reactor of claim 12 wherein the rotary slide comprises cylindrical segments.

15. The plasma reactor of claim 9 wherein the plasma source isolation mechanisms comprise a gas flow arrangement in the processing chamber.

16. The plasma reactor of claim 15 wherein the gas flow arrangement comprises a pressure difference between an isolated plasma source and an un-isolated plasma source.
